(19) United States
(12) Patent Application Publication
(10) Pub. No.: US 2009/0032901 A1
(43) Pub. Date: Feb. 5, 2009

(54) Method of curing hydrogen silsesquioxane and densification in nano-scale trenches

(76) Inventors: Wei Chen, Midland, MI (US); Byung Keun Hwang, Midland, MI (US); Jae-Kyun Lee, Midland, MI (US); Eric Scott Moyer, Midland, MI (US); Michael John Spaulding, Essexvill, MI (US); Sheng Wang, Midland, MI (US)

Correspondence Address: DOW CORNING CORPORATION CO1232, 2200 W. SALZBURG ROAD, P.O. BOX 994, MIDLAND, MI, 48686-0994, US

(21) Appl. No.: 11/919,109

(22) PCT Filed: Jun. 12, 2006
(86) PCT No.: PCT/US2006/020851

§ 371 Date: Oct. 23, 2007

Related U.S. Application Data
(60) Provisional application No. 60/690,825, filed on Jun. 15, 2005.

(51) Int. Cl. H01L 21/762; H01L 23/58

(52) U.S. Cl. 257/510; 438/424; 257/E21.546; 257/E23.002

(57) ABSTRACT

Trenches in a semiconductor substrate are filled by (i) dispensing a film forming material on the semiconductor substrate and into the trenches; (ii) curing the dispensed film forming material in the presence of an oxidant at a first low temperature for a first predetermined period of time; (iii) curing the dispensed film forming material in the presence of an oxidant at a second low temperature for a second predetermined period of time; (iv) curing the dispensed film forming material in the presence of an oxidant at a third high temperature for a third predetermined period of time; and (v) forming filled oxide trenches in the semiconductor substrate. The film forming material is hydrogen silsesquioxane.

### CROSS-REFERENCE TO RELATED APPLICATIONS

None

### FIELD OF THE INVENTION

The invention relates to a method of curing hydrogen silsesquioxane (HSQ) films in nano-scale trenches of high aspect ratios. A high aspect ratio in general means a narrow and deep trench. The narrower the width of the trench relative to the depth of the trench, the higher is the aspect ratio. The curing technique involves a three stage procedure that is carried out at three temperature ranges, in the presence of an oxidant such as moisture steam and/or nitrous oxide, and the like.

### BACKGROUND OF THE INVENTION

Integrated circuit technology uses narrow trenches in semiconductor substrates to isolate circuits such as pre-metal dielectrics (PMD) and shallow trench isolations (STI). Insulating material is deposited into the trenches to form insulation layers, and to planarize the topography. Chemical vapor deposition (CVD) and spin-on glass deposition (SOD) are techniques typically used to fill trenches on semiconductor substrates, to form dielectric layers such as silicon dioxide (SiO₂) and silicon dioxide based layers.

A typical CVD method involves placing a substrate in a reactor chamber where process gases are introduced and heated. This induces a series of chemical reactions that result in the deposition of a desired layer on the substrate. CVD methods can be used to prepare a silicon dioxide film made from silane (SiH₄) or tetraethoxysilane Si(OC₂H₅). Various types of CVD processes are known such as atmospheric pressure CVD, low pressure CVD, or plasma enhanced CVD. However, CVD methods can suffer from the drawback that when trench dimensions approach deep submicron scale, sufficient trench filling becomes difficult. The CVD technique therefore, is not suitable for the nano-scale trench filling with high aspect ratio according to the invention.

In a typical SOD method, a solution containing a film forming material, such as an HSQ resin, is dispersed on to a substrate and spin spread to form a uniform thin film, using certain spin parameters. The spinnability of the solution directly influences the quality and performance of the thin film. After the film forming material is deposited on the substrate, the film forming material is cured. SOD is the technique according to the method of the present invention.

### BRIEF SUMMARY OF THE INVENTION

The invention is directed to a method of filling trenches in a semiconductor substrate. The trenches are filled by:

dispensing a film forming material on the semiconductor substrate and into the trenches;

curing the dispensed film forming material in the presence of an oxidant at a first low temperature for a first predetermined period of time;

curing the dispensed film forming material in the presence of an oxidant at a second low temperature for a second predetermined period of time;

curing the dispensed film forming material in the presence of an oxidant at a third high temperature for a third predetermined period of time; and

forming filled oxide trenches in the semiconductor substrate.

The film forming material is a solution of hydrogen silsesquioxane, and the oxidant can be nitrous oxide, nitric oxide, moisture steam, and the like. The hydrogen silsesquioxane film forming material is deposited on the semiconductor substrate and into the trenches by the spin-on coating method. The first low temperature is from 20-25° C. to 100° C., the second low temperature is from 100-400° C., and the third high temperature is from 800-900° C. If desired, the filled oxide trenches in the semiconductor substrate can be densified in the presence of nitrous oxide at a temperature of 400-800° C. The first, second, and third predetermined periods of time, and the time for the densification, are each 30-60 minutes. These and other features of the invention will become apparent from a consideration of the detailed description.

### BRIEF DESCRIPTION OF THE DRAWING

FIG. 1 is a cross section of a Scanning Electron Microscopy (SEM) image of a film made on a patterned wafer after the film was cured and wet etched.

### DETAILED DESCRIPTION OF THE INVENTION

### Hydrogen Silsesquioxane

The hydrogen silsesquioxane used herein is a preceramic silicon-containing resin, more particularly, a hydridosiloxane resin containing units of the formula HSi(OH)ₓ(OR)_{y}O_{z/2}. R is independently an organic group, which when bonded to silicon through the oxygen atom, forms a hydrolyzable substituent. Suitable R groups include alkyl groups such as methyl, ethyl, propyl, and butyl; aryl groups such as phenyl; and alkenyl groups such as allyl or vinyl. The value of x is 0-2; y is 0-2; z is 1-3; and the sum of x+y+z is 3.

These resins may be (i) fully condensed hydrogen silsesquioxane resins (HSiO_{3/2})ₙ; (ii) resins which are only partially hydrolyzed, i.e., containing some ≡SiOR; and/or (iii) resins which are partially condensed, i.e., containing some ≡SiOH. In addition, the resin may contain less than about 10 percent of silicon atoms having either no hydrogen atoms or two hydrogen atoms, or oxygen vacancies, as well as ≡Si—Si≡ bonds, which can occur during their formation or handling.

Hydrogen silsesquioxane resins are ladder or cage polymers which generally conform to the structure depicted below.

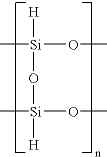

Typically, n has a value of four or more. By way of illustration, when n is four, a bond arrangement for a silsesquioxane cubical octamer is depicted below.

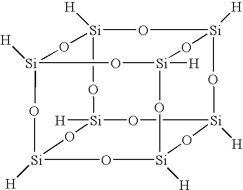

As the series is extended, i.e., n being five or more, double-stranded polysiloxanes of indefinitely higher molecular weight are formed, which contain regular and repeated cross links in their extended structure.

Hydrogen silsesquioxane resins and a method for their preparation are described in U.S. Pat. No. 3,615,272 (Oct. 26, 1971), which is incorporated herein by reference. According to the method in the '272 patent, nearly fully condensed hydrogen silsesquioxane resin containing up to 100-300 parts per million silanol (≡SiOH), can be prepared by hydrolyzing trichlorosilane (HSiCl₃) in a benzene sulfonic acid hydrate medium, washing with aqueous sulfuric acid, and subsequently washing with distilled water until neutral. The solution is filtered to remove insoluble material, and is then evaporated to dryness, leaving a solid resinous polymer in powder form.

U.S. Pat. No. 5,010,159 (Apr. 23, 1991), which is also incorporated herein by reference, teaches another method of hydrolyzing hydridosilanes that are dissolved in a hydrocarbon solvent, with an aryl sulfonic acid hydrate medium to form the resin. A solid resinous polymer in powder form can be recovered by removing the solvent. The solvent can be removed by distilling off the solvent at atmospheric pressure to form a concentrate containing 40-80 percent of the resin, and removing the remaining solvent under vacuum and mild heat.

Other suitable resins are described in U.S. Pat. No. 4,999,397 (Mar. 12, 1991), including those resins produced by hydrolyzing an alkoxy or acyloxy silane in an acidic alcoholic medium, according to Japanese Kokai Patents JP 59-178749 (Jul. 6, 1990), JP 60-086017 (May 15, 1985), and JP 63-107122 (May 12, 1988), all of which are incorporated by reference.

Solutions of the resinous polymer can be formed by simply dissolving or dispersing the pre-ceramic silicon containing resin in a solvent or in a mixture of solvents. Some suitable solvents which can be employed by way of example are aromatic hydrocarbons such as benzene, toluene, and xylene; alkanes such as n-heptane, hexane, octane, and dodecane; ketones such as methyl ethyl ketone and methyl isobutyl ketone (MIBK); linear polydimethylsiloxanes such as hexamethyldisiloxane, octamethyltrisiloxane, decamethyltetrasiloxane, and mixtures thereof; cyclic polydimethylsiloxanes such as octamethylcyclotetrasiloxane, decamethylcyclopentasiloxane, dodecamethylcyclohexasiloxane, and mixtures thereof; esters such as butyl acetate and isoamyl acetate; or ethers such as diethyl ether and hexyl ether. Generally, enough solvent is used to form the solutions, which typically range from a solids content of 10-85 weight percent of the resin.

The present invention is based on the discovery that oxidants such as nitrous oxide (N₂O), nitric oxide (NO), oxygen (O₂), moisture steam, and the like, when used in curing film forming materials at high temperatures, often cause the film forming material in the top portion of a nano-scale trench to become more densified than the film forming material in the bottom portion of the nano-scale trench. During a high temperature cure, for example, the film forming material in the top portion of the trench comes into contact with the oxidant before the oxidant reaches the bottom portion of the nano-scale trench. The result is that oxidation occurs in the film forming material in the top portion of the trench before the film forming material in the bottom portion of the nano-scale trench is sufficiently oxidized. This prevents the formation of a fully densified and fully filled nano-scale trench. The cured film forming material in the top portion of the nano-scale trench forms a dense skin layer that prevents any further penetration of the oxidant and the film forming material into the nano-scale trench. As a consequence, the film forming material in the bottom portion of the nano-scale trench cannot be fully cured to the same extent as the film forming material in the top portion of the nano-scale trench.

This undesirable consequence is avoided by the method according to the invention that allows one skilled in the art to obtain fully cured HSQ in nano-scale trenches. The method permits the oxidant and the film forming material to diffuse and/or penetrate fully into the nano-scale trench before the dense skin layer is formed. The oxidant is then able to react with Si—H groups in the HSQ film forming material with the result that silanol groups are formed. These reactions are carried out at relatively low temperature ranges that allow both the oxidant and the film forming material to move into the bottom of the nano-scale trench. Moisture steam is the preferred oxidant for the low temperature cures. At low temperature, the dense skin layer has less possibility to form. Moisture steam can therefore penetrate and/or diffuse fully into the bottom portion of the nano-scale trench. The moisture steam oxidant can then reacts with the SiH groups in the HSQ film forming material as noted above forming silanol groups.

The moisture steam temperature should be maintained in a sufficiently low range so that the dense skin layer does not form, yet be maintained at a range sufficient to allow the moisture steam and the film forming material to penetrate into the depth of the nano-scale trench. After allowing sufficient time for the reactions to occur at low temperature, the two low temperature curing steps are followed by a third high temperature annealing step in an oxidation environment. Thus third step causes the silanol groups in the film forming material to condense, and silicon oxide is formed in the nano-scale trench. A fully densified nano-scale trench is therefore obtained exhibiting good wet etch resistance. This indicates that the method can be used to produce dense filled material in the trenches.

The temperature range for the three step cure are (i) from room and/or ambient temperature of 20-25° C. to 100° C. for the first low temperature cure; (ii) from 100-400° C. for the second and/or soaking low temperature cure; and (iii) from 800-500° C. for the third high temperature and/or annealing cure. The first low temperature cure and the second and/or soaking low temperature cure are carried out in the presence of moisture steam as the preferred oxidant. The third high temperature and/or annealing cure is carried out in the presence of moisture steam or nitrous oxide as preferred oxidants. Other common oxidants can be used provided their use has no detrimental effect upon the resulting wafer surface. The filled oxide trenches in the semiconductor substrate can be further densified in the presence of nitrous oxide at a temperature of 400-800° C. The time period allowed during each of the three step cures and the densification should be between 30-60 minutes.

The substrate is a semiconductor substrate having trenches thereon. The semiconductor substrate is not specifically restricted, and can be any semiconductor substrate used in the manufacture of an integrated circuit. For example, the substrate may be a silicon wafer. The film forming material is applied by spin-on deposition (SOD). When using spin-on deposition, the conditions will depend on various factors including the desired thickness of the film formed by the method, and the specific film forming material selected. Typically, the semiconductor substrate onto which the film forming material is deposited is spun at a speed of at least about 500 revolutions per minute (rpm) to about 6,000 rpm. The time for deposition is at least about 5 seconds to about 3 minutes. The film forming material is deposited in an amount of about 0.4 milliliters/square centimeter. However, the spin speed, spin time, and the amount of the film forming material used can be adjusted to produce a film having a desired thickness. For example, the desired thickness can adjusted to about 800 nanometers.

The method can include an optional step of removing all or a portion of the solvent after SOD and before cure. The solvent may be removed by any convenient means such as heating under ambient or reduced pressure. The solvent may be removed by heating to a temperature of at least about 250° C. to about 400° C.

The method can produce substantially crack free films of at least about 800 nanometers in thickness. The method can produce films having good mechanical strength. The method can produce films having a dielectric constant of up to about 4. The method can produce films comprising silicon and oxygen in amounts such that a molar ratio of silicon to oxygen is about 1 to about 2. The method produces films having good resistance against invasive wet etching techniques during processes to make electronic devices. For example, films can be prepared having etch resistance expressed as film loss, in the trenches of 70-100 angstroms per minute, when exposed for one minute to an aqueous solution of 200:1 hydrofluoric acid at room temperature.

The method described above can be used to form films used as a dielectric layer in a wide variety of applications. For example, the method can be used to form a pre-metal dielectric (PMD) layer, shallow trench isolation (STI), an inter-layer dielectric (ILD) layer, and a planarizing layer in an electronic device.

The method herein is illustrated in the formation of a STI layer in a dynamic random access memory (DRAM) device. In a typical process to make a DRAM device, a silicon wafer is provided with a plurality of ceramic gates thereon. These gates have trenches therebetween. Aspect ratios (W:D) can be 1:10, preferably 1:8. These trenches can have widths that vary from 10-100 nanometers.

The method herein can be used in other devices in addition to DRAM devices. For example, the method can be used to form dielectric layer in a LOGIC device or a memory device such as a DRAM, or a static random access memory (SRAM). The method can be used to form dielectric layers in a central processing unit (CPU) device. A CPU can have from 10-12 dielectric layers. The method can also be used for trench isolation such as shallow trench isolation (STI) in LOGIC and memory devices. The method can be used to fill a trench or hole on a semiconductor substrate to isolate p- and n-junctions, and prevent migration of dopants.

### EXAMPLES

The following examples are set forth in order to illustrate the invention in more detail.

### Example 1

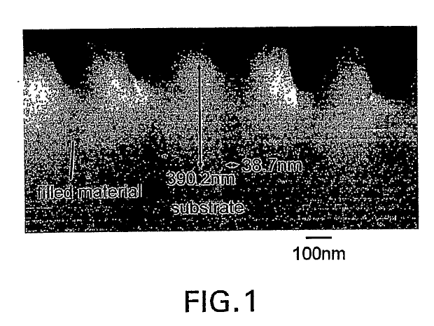

Two finely filtered HSQ solutions containing 4 percent by weight and 8 percent by weight respectively of HSQ in octamethyltrisiloxane were used. The film was spin coated on a silicon wafer surface. In the first low temperature cure step, the film was initially maintained at 100° C. in a moisture steam environment for 30 minutes. In the second low temperature cure step, the temperature was raised to 250° C. in the moisture steam environment for one hour. During these two low temperature cure steps, the moisture steam remained in the trenches and reacted with the HSQ. The film was then further cured in the third high temperature cure step at 800° C. in a moisture steam or nitrous oxide environment for one hour. Etching was carried out by exposing the film to an aqueous 200:1 solution of hydrofluoric acid for 60 seconds, and determining film loss. The resulting film is shown in FIG. 1.

### Example 2

### Comparison

Example 1 was repeated using a normal oxidation cure without moisture steam at 800° C. No etch resistance of the film was observed. The filled material in the trenches was completely removed.

### Example 3

Example 1 was repeated, and the cured HSQ films in the nano-scale trenches of the silicon wafer were further densified under a nitrous oxide (N₂O) environment. In particular, the curing of the thin film of HSQ resin coated on the silicon wafer in a nitrous oxide ambient was determined using different temperatures. The wet etch resistance in the nano-scale trenches was determined using the same HF etch procedure in Example 1. The process time for each determination was one hour. As shown in Table 1, the film loss of HSQ films cured in nitrous oxide in diluted HF solutions was decreased, compared to HSQ films cured under an oxygen or nitrogen environment. In particular, HSQ films cured under nitrous oxide at 800° C. had film loss comparable to that of a thermal oxide film. The values for thermal oxide film in Table 1 are published data in the literature. Table 1 also shows that the mechanical properties (i.e., hardness and modulus) of HSQ films cured under nitrous oxide were increased as evidences by the high values of hardness and modulus.

TABLE 1
Thin Film Properties of Cured HSQ Films at Different Curing
Temperatures

| | Film Loss, 200:1 | | | |
|---|---|---|---|---|
| | HF Wet Etch, | | | Dielectric |
| Temperature, | 1 Minute, | Modulus | Hardness | Constant |
| Oxidant | Angstroms (A) | (Gpa) | (Gpa) | @ 1 MHz |
| 400° C., N₂ | 2,800 | 4.25 | 0.73 | 2.9 |
| 400° C., N₂O | 324.8 | 12.3 | 1.72 | 3.2 |
| 550° C., N₂O | 130.2 | 58.5 | 4.26 | 5.9 |
| 650° C., N₂O | 92.4 | 65.0 | 4.91 | 5.5 |
| 750° C., N₂O | 39.2 | 66.0 | 5.80 | 4.5 |
| 800° C., N₂O | 22.4 | 73.0 | 6.70 | 4.2 |
| 800° C., O₂ | 81.2 | 56.0 | 4.00 | 4.7 |
| Thermal | 14 | 70.0 | 7.04 | 4.2 |
| Oxide | | | | |

1. A method of filling trenches in a semiconductor substrate comprising:
(i) dispensing a film forming material comprising a solution of hydrogen siloxane on the semiconductor substrate and into the trenches;
(ii) curing the dispensed film forming material in the presence of an oxidant at a first low temperature of from 20-25° C. to 100° C. for a first predetermined period of time;
(iii) curing the dispensed film forming material in the presence of an oxidant at a second low temperature from 100-400° C. for a second predetermined period of time;
(iv) curing the dispensed film forming material in the presence of an oxidant at a third high temperature of from 800-900° C. for a third predetermined period of time; and
(v) thereby forming filled oxide trenches in the semiconductor substrate.

2. (canceled)

3. The method according to claim 1 wherein the oxidant is selected from the group consisting of nitrous oxide, nitric oxide, oxygen, and moisture steam.

4. The method according to claim 1 wherein the film forming material is dispensed on the semiconductor substrate and into the trenches by spin-on deposition.

5. (canceled)

6. (canceled)

7. (canceled)

8. The method according to claim 1 wherein the first, second, and third predetermined periods of time are each 30-60 minutes.

9. The method according to claim 1 further comprising (vi) densifying the filled oxide trenches in the semiconductor substrate in the presence of nitrous oxide at a temperature of 400-800° C.

10. A semiconductor substrate having filled trenches prepared by the method according to claim 1.

11. A method of filling trenches in a semiconductor substrate comprising:
(i) dispensing a hydrogen silsesquioxane film on the semiconductor substrate and into the trenches;
(ii) curing the dispensed hydrogen silsesquioxane in the presence of an oxidant at a temperature from 20-25° C. to 100° C. for a first predetermined period of time;
(iii) curing the dispensed hydrogen silsesquioxane in the presence of an oxidant at a temperature from 100-400° C. for a second predetermined period of time;
(iv) curing the dispensed hydrogen silsesquioxane in the presence of an oxidant at a temperature from 800-900° C. for a third predetermined period of time; and
(v) forming filled oxide trenches in the semiconductor substrate.

12. The method according to claim 11 wherein the oxidant is selected from the group consisting of nitrous oxide, nitric oxide, oxygen, and moisture steam.

13. The method according to claim 11 wherein the hydrogen silsesquioxane film is dispensed on the semiconductor substrate and into the trenches by spin-on deposition.

14. The method according to claim 11 wherein the first, second, and third predetermined periods of time are each 30-60 minutes.

15. The method according to claim 11 further comprising (vi) densifying the filled oxide trenches in the semiconductor substrate in the presence of nitrous oxide at a temperature of 400-800° C.

16. A semiconductor substrate having filled trenches prepared by the method according to claim 11.
